(19) United States
(12) Patent Application Publication
(10) Pub. No.: US 2006/0043513 A1
(43) Pub. Date: Mar. 2, 2006

(54) Method of making camera module in wafer level

(76) Inventor: Deok-Hoon Kim, An-Yang-si (KR)

Correspondence Address: ROSENBERG, KLEIN & LEE, 3458 ELLICOTT CENTER DRIVE-SUITE 101, ELLICOTT CITY, MD, 21043, US

(21) Appl. No.: 11/095,456

(22) Filed: Apr. 1, 2005

Related U.S. Application Data
(60) Provisional application No. 60/606,500, filed on Sep. 2, 2004.

(51) Int. Cl. H01L 31/062

(52) U.S. Cl. 257/433

(57) ABSTRACT

A plurality of photo-sensing device packages are provided. The packages are formed on unit substrate portions of a substrate to each include at least one photo-sensing semiconductor die. The substrate is formed of a material substantially transparent to light within a predetermined range of wavelengths, with each unit substrate portion being provided with front and backside surfaces on opposite sides thereof. Each photo-sensing semiconductor die defines at least one photo-sensing area opposing the front surface of one unit substrate portion for receiving light impinging upon its backside surface and passing therethrough. A plurality of lens housings are also provided on the substrate, each including at least one lens element disposed in optical alignment with said photo-sensing semiconductor die of one said unit substrate. The plurality of photo-packages are formed by dicing the substrate to separate the unit substrate portions one from the other.

### RELATED U.S. APPLICATION DATA

This Application is based on U.S. Provisional Patent Application, Ser. No. 60/606,500, filed 2 Sep. 2004.

### BACKGROUND OF THE INVENTION

1. Field of the Invention

The present invention relates generally to electronic packaging of photo-sensing electronic devices. More specifically, the present invention relates to the fabrication of digital camera modules for use in various applications such as cellular telephone devices.

2. Related Art

Novel electronic packaging techniques for applications incorporating photo-sensors are disclosed in co-pending U.S. patent application Ser. Nos. 10/692,816, 60/507,100, 10/829,273, and 60/536,536. FIGS. 1-2 illustratively show schematic cross-sectional views of certain exemplary electronic packages realized by such techniques, fuller descriptions of which are contained in such co-pending applications.

The package 100 illustrated in FIG. 1 is typically suited for general applications, while the package 200 illustrated in FIGS. 2A-2B is particularly well-suited for cellular telephone camera module applications, where compact size remains invariably among paramount concerns.

In packages of the type shown, a photo sensor device 110, 210 defines a certain photo-sensing area 112, 212—defined at a center portion of a top surface in the configurations illustrated. A substrate 120, 220 having sufficient transmittance for light within a certain wavelength range of interest is provided with the photo-sensor device 110, 210. The substrate 120, 220 may be formed, for example, of a glass material where the photo-sensor device 110, 210 is to sense light within the visual range in wavelength. Electrical interconnection lines 122, 222 and one or more passivation layers 124, 224 are formed over a front surface 121, 221 of the substrate 120, 220 (bottom surface of the substrate in the configuration as illustrated); and, flipchip interconnections 130, 230 are typically employed between the photo-sensor device 110, 210 and substrate 120, 220. A sealing structure 140, 240 is also provided for protecting the side wall portion of the photo-sensor device 110, 210 and sealing the photo-sensing area 112, 212 that it extends about. Other structures such as solder balls 150 (in the case of the package illustrated in FIG. 1) and pads 250 (in the case of the package illustrated in FIG. 2) for interconnection to external circuitry and/or components, decoupling capacitances 260, and the like are also typically provided in the resulting package using suitable means known in the art.

In the electronic package configuration illustrated in FIGS. 1 and 2, a substrate substantially of wafer or rectangular panel form, having a sufficiently expansive area to establish a plurality of unit substrates 120, 220 thereon is used. Once the necessary fabrication and assembly processes have occurred to form an array of unit packages on a common substrate wafer or panel, dicing of the resultant unitary structure is performed to separate the unit packages 100, 200.

Although a plurality of unit packages 100, 200 may be concurrently fabricated in this manner, dicing does not yield a completed module in many image sensing applications. Each of the separated unit packages 100, 200 shown in FIGS. 1 and 2, for instance, must be equipped additionally with a lens housing (or barrel) attached thereto for holding one or more optical lens elements, as well as an IR cut filter glass where the given substrate is without any IR cut filter coating. This necessitates considerable post-dicing processes upon the individual packages to so equip each separated unit package 100, 200 for actual use in a given application.

There is, therefore, a need for an approach whereby a plurality of lens housing or other such elements requisite to a substantially complete photo-sensing module may be mounted or otherwise coupled to the substrate before its dicing. There is a need for concurrent cost-effective processing in this respect upon the unit packages formed on the substrate prior to their separation by dicing.

### SUMMARY OF THE INVENTION

It is a primary object of the present invention provide an effectively yet efficiently fabricated photo-sensing device package.

It is another object of the present invention to provide a plurality of substantially complete photo-sensing device packages on a common substrate for subsequent separation by dicing.

It is yet another object of the present invention to provide a substrate on which a plurality of substantially complete photo-sensing modules having respective optical element housings formed thereon prior to separation by dicing.

These and other objects are attained by the method and assembly of the present invention, whereby a plurality of unit substrate portions are defined on a substrate formed of a material substantially transparent to light within a predetermined range of wavelengths. The unit substrate portions are defined to each include front and backside surfaces on opposite sides thereof. A plurality of photo-sensing semiconductor dice are coupled to the substrate, each photo-sensing semiconductor die defining at least one photo-sensing area opposing the front surface of one unit substrate portion for receiving light impinging upon the backside surface and passing through this unit substrate portion. A plurality of lens housings are coupled to the substrate to pre-form a plurality of said photo-sensing device packages. Each lens housing includes at least one lens element, and is disposed on the backside surface of one unit substrate portion, with each lens element thereof being disposed in optical alignment with the semiconductor die disposed over the unit substrate portion's front surface. The substrate is thereafter diced to separate the unit substrate portions one from the other and thereby form a plurality of photo-sensing device packages.

### BRIEF DESCRIPTION OF THE DRAWINGS

FIG. 1 is a schematic cross-sectional view of an illustrative photo-sensing electronic package formed in accordance with one exemplary embodiment of the invention disclosed in co-pending application Ser. No. 10/692,816;

FIG. 2A is a schematic cross-sectional view of an illustrative photo-sensing electronic package formed in accordance with one exemplary embodiment of the invention disclosed in co-pending application Ser. No. 10/892,273;

FIG. 2B is a bottom plan view of the photo-sensing electronic package embodiment illustrated in FIG. 2A;

FIG. 3 is a schematic cross-sectional view of a plurality of partial photo-sensing device packages, as illustrated in FIG. 1, formed on respective unit substrate portions of a substrate in accordance with one exemplary embodiment of the present invention;

FIG. 4 is a schematic cross-sectional view of a plurality of partial photo-sensing device packages, as illustrated in FIGS. 2 and 2A, formed on respective unit substrate portions of a substrate in accordance with another exemplary embodiment of the present invention;

FIG. 5 is a schematic cross-sectional view of a plurality of photo-sensing device packages having a plurality of lens housings formed in accordance with one exemplary embodiment of the present invention at respective unit substrate portions of the substrate shown in FIG. 3; and,

FIG. 6 is a schematic cross-sectional view of a plurality of photo-sensing device packages having a plurality of lens housings formed in accordance with another exemplary embodiment of the present invention at respective unit substrate portions of the substrate shown in FIG. 4.

### DETAILED DESCRIPTION OF THE PREFERRED EMBODIMENTS

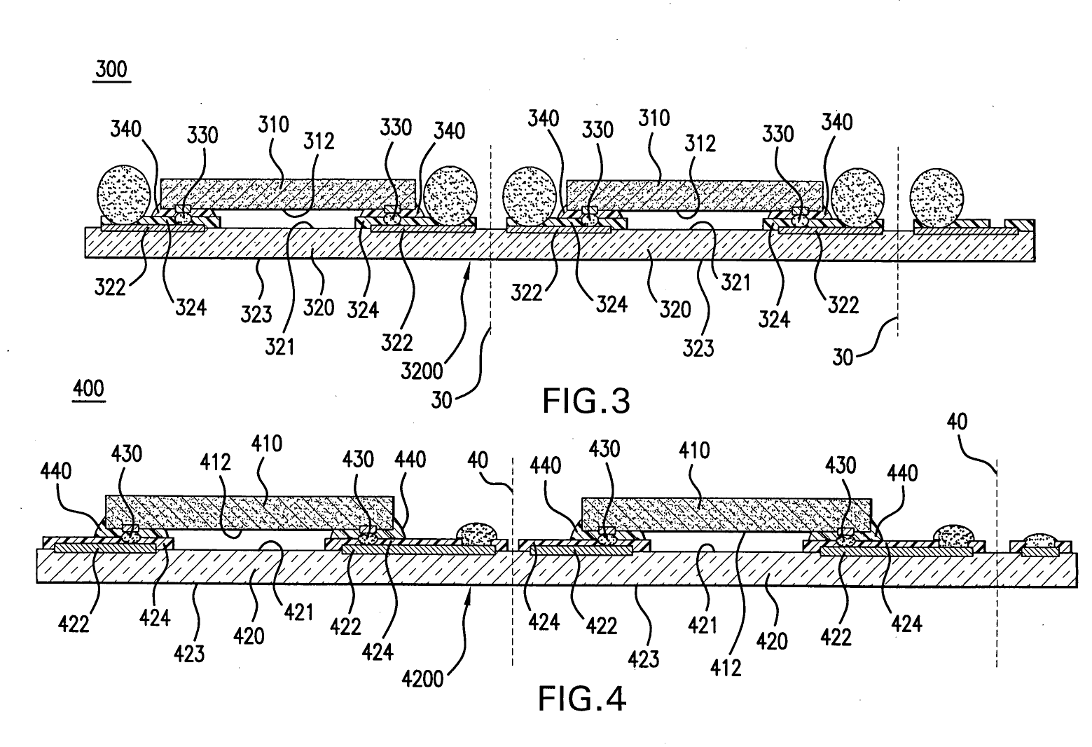

In forming each package 300, 400 illustrated shown in FIGS. 3-4, a photo-sensing semiconductor wafer is typically provided with a plurality of dice, each die having integrated circuitry formed on a front surface of the wafer, with a plurality of bonding pads. The wafer has formed over its front surface a patterned passivation layer for protecting the integrated circuitry underneath. Openings are provided accordingly in the patterned passivation layer at the bonding pads. Each of the resulting photo-sensing dice 110, 210 defines at least one photo-sensing area 112, 212 at its front, or light receiving, surface.

Wafer bumping is a well-known technique that has been widely used since its initial teaching, as reflected in U.S. Pat. No. 3,292,240 entitled “Method of Fabricating Microminiature Functional Components,” assigned to IBM. A typical wafer bumping process includes forming at least one patterned metal layer for making bump pads connected to bonding pads on the wafer. Metallurgy used for flipchip bump pads is commonly referred to as under bump metallurgy (UBM) and typically utilizes a multilayered structure to provide multiple functional advantages, such as good adhesion to bonding pad, good barrier against diffusion of bump material, and the like.

Many bump materials are known in the art. They include Gold, Nickel, Copper, and solder alloys, which are mainly Tin-based alloys.

Various techniques are known in the art for depositing UBM. Suitable techniques include sputtering, electroplating, electroless plating, or the like. Also various techniques are known in the art for forming a bump. An electroplating technique is often used in forming a Gold or Copper bump, while an electroless deposition technique is often used in forming a Nickel or Copper bump. In the case of a solder bump, either an electroplating technique or a printing technique is typically used.

In accordance with the present invention, the photo-sensing semiconductor wafer may preferably, though not necessarily, include UBM pads formed over the bonding pads, depending on the particular flipchip bumping and mounting technology actually used. Alternatively, the photo-sensing semiconductor wafer of the present invention may, if necessary, further include flipchip bumps formed over the UBM pads.

A substrate is normally fabricated separately. This substrate is preferably disposed, initially, in wafer or panel form having a large area to form a plurality of unit substrates in a batch process, in much the same manner as the semiconductor wafer is formed with a plurality of dice fabricated thereon. Preferably, the substrate material includes in suitable degrees: transparency, mechanical rigidity, and chemical stability—as required by the intended application.

In the photo-sensing applications illustrated, the substrate material is substantially transparent to a particular wavelength, or a particular range of wavelengths, so as to transmit light impinging upon a back side thereof to a photo-sensing device disposed at or near its front side. Suitable substrate materials preferably include, but are not limited to, glasses, quartz, sapphire, silicon, and others, the actual choice of particular substrate material depending on the wavelength range of interest in the intended application among other pertinent factors. Exemplary applications may employ photo-sensing devices operating at wavelengths in, for instance, the x-ray, ultra-violet, visible, or infrared spectra.

The substrate material must possess not only sufficient chemical resistance and mechanical stability to withstand the temperature and processing extremes to which it would be subjected during the necessary fabrication steps, but also sufficient resistance to expected environmental factors to support the resulting devices' expected service life. A preferable substrate material for photo-sensing devices operating in the visible range of wavelengths is any suitable glass material known in the art to be adapted for optical applications. Such glass materials tend to possess suitable degrees of chemical and temperature stability, and to be readily available at reasonable cost, and from many sources.

Depending on the requirements of the intended application, the substrate may be coated with at least one thin film layer on one or more of its surfaces to enhance the light transmission therethrough. Such coating may be of the so-called anti-reflection coating (ARC) type well known to persons versed in the optical art, which serves to minimize the reflection loss of light over the entire spectrum of interest. Similarly, the substrate may be coated with at least one thin film layer on one or more of its surfaces to enhance or reduce the transmission therethrough of light at a specific range of wavelengths. Such coatings are of the “optical filtering” type also known in the art of optics. One example is an infrared (IR) cut filter coating used in much the same manner an IR cut filter glass is used for a chip-on-board (COB) cellular phone camera module.

At least one patterned metal layer 322, 422 is formed on the front surface 321, 421 of the substrate 3200, 4200 for making electrical interconnection lines. Then, at least one patterned passivation layer 324, 424 is formed on the patterned metal layer 322, 422 for protecting the interconnection lines defined thereby. This patterned passivation layer 324, 424 is formed with openings for making bonding pads at the substrate side. These bonding pads enable electrical interconnections 330, 430 to be made between the interconnection lines of the substrate 3200, 4200 and the photo-sensor 320, 420, external systems, and other components, if any.

In accordance with the present invention, the substrate 3200, 4200 may preferably, though not necessarily, further include UBM pads formed over the bonding pads if the bonding pads themselves are not sufficiently suitable for making flipchip bumps. Whether or not they are sufficiently suitable depends primarily upon the particular bonding pad material and flipchip technology used. Also in accordance with the present invention, the substrate 3200, 4200 may, though not necessarily, further include flipchip bumps formed over the UBM pads.

At least one photo-sensor die is mounted on each unit substrate 320, 420 defined on the substrate 3200, 4200, preferably by using a suitable flipchip assembly process known in the art. Flipchip assembly processes are of many suitable varieties, depending on the bump material used. In accordance with one of the most commonly used flipchip mounting processes, a flipchip joint is formed using a solder bump. With this process, a solder bumped die 310, 410 is placed onto a unit substrate 320, 420 having corresponding solder bump pads, then heated to the characteristic melting temperature of the solder material, with an application of flux.

Other known processes include thermo-sonic or thermo-compression bonding for joining gold bump to any suitable bonding pad. The thermo-compression bonding process may also be used with Isotropic Conductive Adhesive (ICA), Anisotropic Conductive Adhesive (ACA), or Anisotropic Conductive Film (ACF) in joining, for instance, gold, Nickel, or copper bump to any suitable bump or pad.

The electronic package 300, 400 formed in accordance with the present invention is not limited to any specific flipchip bump material or to any flipchip assembly process. The particular choice of such material and process will depend upon the specific requirements of the intended application.

The electronic package in accordance with a preferred embodiment of the present invention includes a sealing structure 440 filling the gap between the photo-sensing semiconductor die 310, 410 and unit substrate 320, 420 to define an enclosed cavity at the photo-sensing area 312, 412 of the photo-sensing semiconductor die 310, 410.

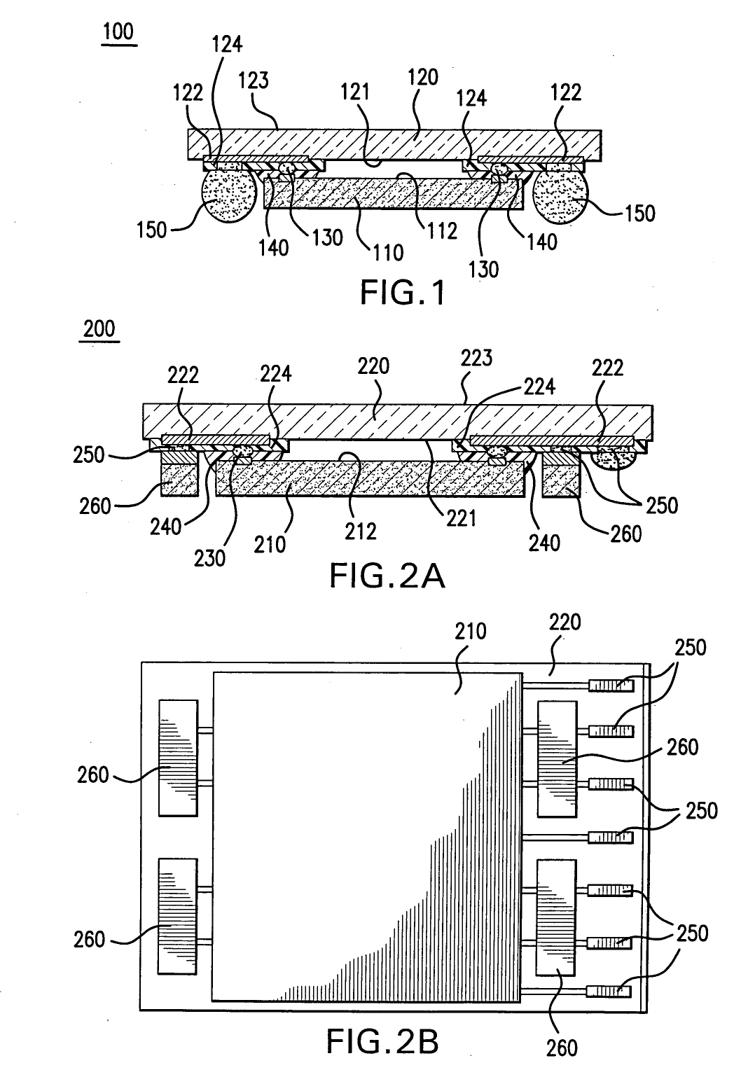

As FIGS. 3 and 4 schematically illustrate, a plurality of package structures such as shown in FIGS. 1 and 2, are formed on a common unitary substrate 3200, 4200. The necessary fabrication and assembly processes described in preceding paragraphs have been completed at the stage illustrated to form the package structures 300, 400 shown; however, dicing to separate the batch produced structures 300, 400 into separate unit packages has yet to occur.

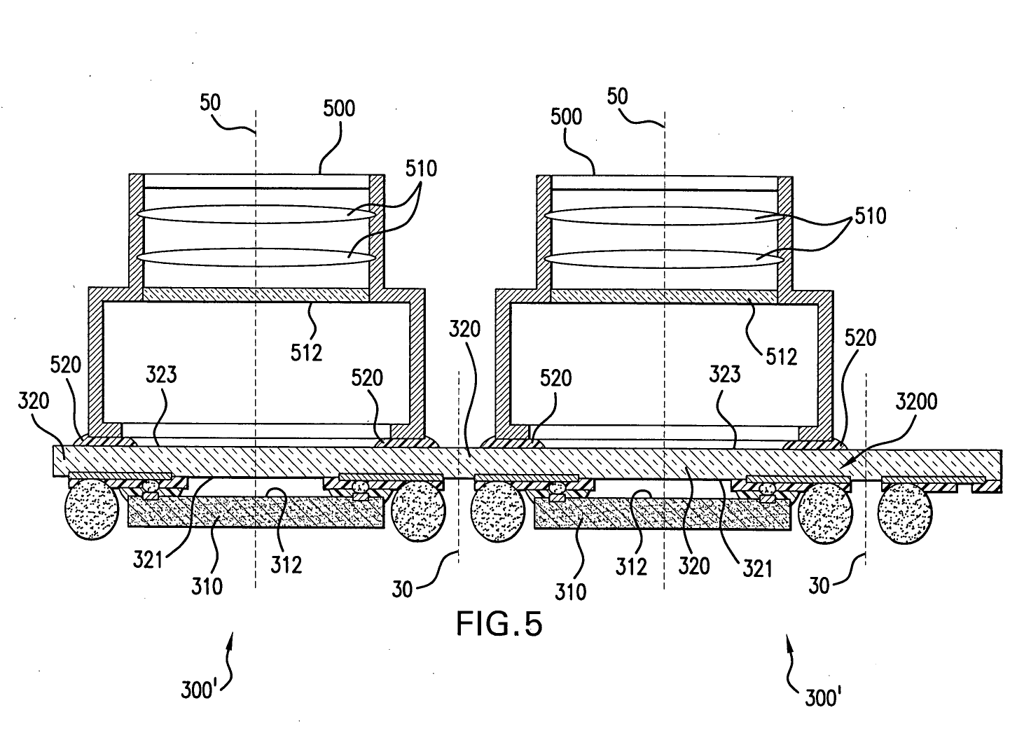

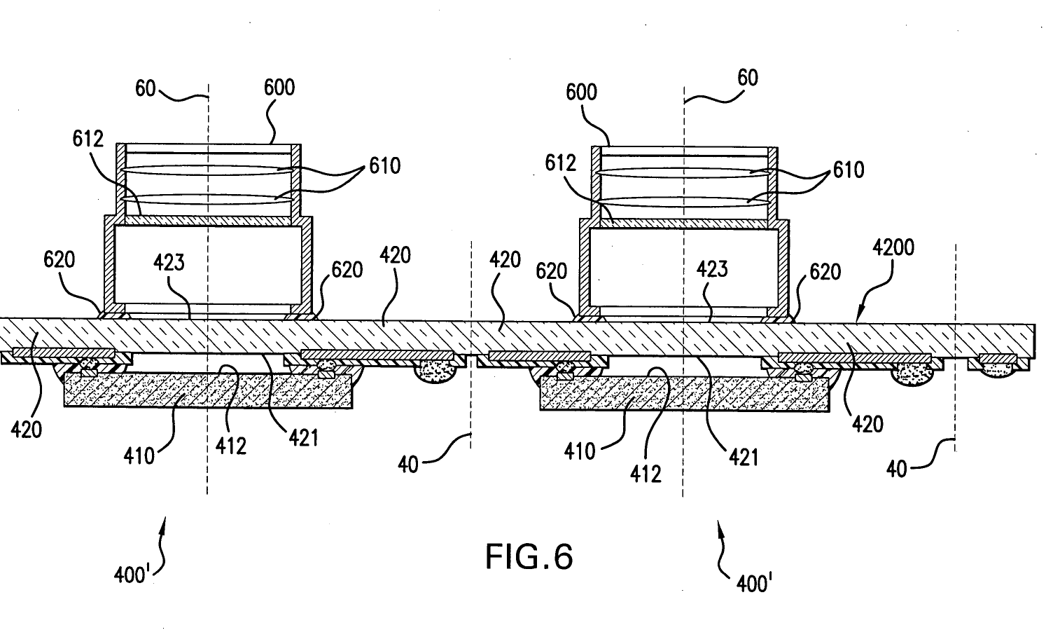

In accordance with one aspect of the present invention, the substrate 3200, 4200 is, prior to dicing, preferably flipped and placed onto a table using suitable pick-and-place equipment. Additional elements requisite to completion of the desired photo-sensing modules at the respective unit package structure are then mounted to the back side 323, 423 of the un-diced substrate 3200, 4200. For camera module applications shown in FIGS. 5-6, for instance, a plurality of lens housing assemblies 500, 600 are mounted onto the back side 323, 423 of the un-diced substrate 3200, 4200 using any suitable pick-and-place operation known in the semiconductor packaging art.

Typically, such operation includes a general pattern aligning process. A pattern recognition system (PRS) camera is provided in this process on the given pick-and-place equipment to effectively look down the length of the substrate and detect alignment marks to determine a given unit substrate's image center location. The equipment then places a lens housing assembly 500, 600 accordingly, to suitably align with the image center 50, 60 of the given photo-sensor 310, 410. This serial pick-and-place operation continues until each unit substrate 320, 420 is suitably provided with a lens housing 500, 600.

Each lens housing 500, 600 in the exemplary embodiment shown forms an assembly which preferably includes at least one lens element 510, 610 held in a barrel-type or other suitable structural configuration. Where the given unit substrate 320, 420 is without any IR cut filter coating, the assembly further includes an IR cut filter element disposed as shown, for example.

Preferably, each lens housing 500, 600 is attached to a unit substrate 320, 420 by an adhesive material 520, 620 applied therebetween. Epoxy adhesive is one example of a suitable material for this application. Such adhesive material is applied via a pattern, whereby the epoxy is preferably applied only on those areas where the lens housing 500, 600 would actually contact the unit substrate 320, 420 for attachment. Sufficient care must be taken to prevent the entry of residual epoxy material into the unit substrate's image sensing area 312, 412.

Numerous methods are known in the art for applying such epoxy adhesive material. A suitable screen or stencil printing process of applying epoxy over select portions of the entire area of the substrate 3200, 4200 may be employed, as may a suitable needle dispensing process. A suitable stamping process, whereby epoxy is applied over select portions of the entire area of the substrate 3200, 4200 at once may, be employed as well.

This epoxy stamping process may be employed in certain embodiments serially upon each unit substrate 320, 420. That is, epoxy is applied onto each unit substrate 320, 420 defined on the substrate 3200, 4200, using the lens housing 500, 600 itself as a stamping tool. In an exemplary application of such process, each lens housing 500, 600 to be placed on the substrate 3200, 4200 is first picked up, then dipped onto a table holding a thin layer of epoxy adhesive material thereon. The lens housing 500, 600, having acquired from the dipping a layer of epoxy adhesive material at its bottom portions, is then placed onto the appropriate portion of the substrate 3200,4200.

The thickness of the epoxy adhesive is preferably, though not limited to, approximately 5-100 micrometer. Subsequent curing may be necessary depending on the characteristics of the epoxy adhesive material used. Some such materials are thermally curable while others are ultra-violet (UV) curable. Some materials, such as snap-curable materials, require very short time to cure, while some materials, such as thermally curable materials, require a relatively longer time to cure.

In accordance with the present invention, dicing (or sawing) follows suitable attachment of the lens housings 500, 600 to the substrate 3200, 4200. This process separates the unit substrates 320, 420 defined by the large overall substrate 3200, 4200, along the dicing lines 30, 40, to yield a plurality of substantially complete modules, or device packages 300′, 400′.

Several advantages are thereby realized in accordance with the present invention. Contrast with the approach of first separating the unit substrates 320, 420 then attaching a lens housing 500, 600 onto each unit substrate 320, 420, wherein a pick-and-place machine must look down the unit package to determine the package center (or image center), and thereafter pick-up and placing a lens housing 500, 600 on the package to ensure its image center alignment with that of the package. In an exemplary process carried out in accordance with the present invention, a pick-and-place machine need only look down the un-diced, common substrate 3200, 4200 and to identify certain alignment marks. This is sufficient to determine the locations of all unit substrates 320, 420, as such unit substrates 320, 420 are preferably defined on the substrate 3200, 4200 to be located the same stepping distance apart from one another in the x and y directions, for instance.

The pick-and-place equipment may then pick-and-place all lens housings 500, 600 one by one on their respectively defined unit substrates 320, 420, sequentially without undue pause or interruption therebetween. The need to re-initiate, re-align, re-calibrate, or otherwise reset the process and machinery inherent to mounting on a package-by-package basis is thus obviated. Consequently, processing costs are significantly lessened, as are the time, complexity, and effort required for processing.

The unique package formed in accordance with the present invention is applicable to all types of photo sensors or photo detectors fabricated with various types of technologies known in the art, such as CCD or CMOS. The present invention is applicable wherever area image sensors are used, such as in camcorders, digital still cameras, PC cameras, mobile phone cameras, PDA and handheld cameras, security cameras, toys, automotive equipment, biometrics, and the like. The present invention is also applicable to linear array image sensors such as those used in fax machines, scanners, bar code readers and scanners, digital copiers, and the like. It is equally applicable in packaging non-imaging photo-sensors such as single diode or four-quadrant diodes used in motion detectors, light level sensors, positional or tracking systems, and the like. Additionally, the present invention is applicable to other general electronic packages that require sealing only at particular predetermined areas.

Although this invention has been described in connection with specific forms and embodiments thereof, it will be appreciated that various modification other than those discussed above may be resorted to without departing form the spirit or scope of the invention. For example, equivalent elements may be substituted for those specifically shown or described, certain features may be used independently of other features, and in certain cases, particular combinations of fabrication or assembly steps may be reversed or interposed, all without departing from the spirit or scope of the invention as defined in the appended claims.

What is claimed is:

1. An assembly having a plurality of pre-formed photo-sensing device packages for dicing one from the other comprising:
a. a substrate formed of a material substantially transparent to light within a predetermined range of wavelengths, said substrate defining a plurality of unit substrate portions each having front and backside surfaces on opposite sides thereof;
b. a plurality of photo-sensing semiconductor dice coupled to said substrate, each said photo-sensing semiconductor die defining at least one photo-sensing area opposing said front surface of one said unit substrate portion for receiving light impinging upon said backside surface and passing through said unit substrate portion; and,
c. a plurality of lens housings each coupled to said backside surface of one said unit substrate portion, each said lens housing including at least one lens element disposed in optical alignment with said semiconductor die disposed over said front surface of said unit substrate portion.

2. The assembly as recited in claim 1 wherein each said lens housing is adhesively attached to said backside surface of one said unit substrate portion.

3. The assembly as recited in claim 2 wherein each said lens housing is attached by an epoxy adhesive joint to said backside surface of one said unit substrate portion.

4. The assembly as recited in claim 1 wherein said predetermined range of wavelengths includes the visible range of wavelengths.

5. The assembly as recited in claim 4 wherein said substrate is formed of a glass material substantially transparent to light in the visible range of wavelengths, and each said photo-sensing semiconductor die is spaced from said front surface of one said unit substrate portion by a gap.

6. The assembly as recited in claim 5 further comprising a sealing structure disposed between each said photo-sensing semiconductor die and said unit substrate portion to extend about and enclose said gap to define a sealed cavity between said photo-sensing area and a portion of said unit substrate portion front surface.

7. The assembly as recited in claim 1 wherein each said unit substrate portion includes an optical coating to vary the transmittance therethrough of light within said predetermined range of wavelengths.

8. The assembly as recited in claim 3 wherein each said unit substrate portion includes at least one patterned metal layer formed on said front surface thereof, at least one patterned passivation layer formed on said patterned metal layer having a plurality of openings to define a plurality of bonding pads.

9. The assembly as recited in claim 8 wherein each said photo-sensing semiconductor die has formed thereon a plurality of bonding pads connected to said substrate by a plurality of flipchip bumps.

10. A method of fabricating a plurality of photo-sensing device packages comprising the steps of:
(a) establishing a substrate formed of a material substantially transparent to light within a predetermined range of wavelengths;
(b) defining on said substrate a plurality of unit substrate portions each having front and backside surfaces on opposite sides thereof;
(c) coupling a plurality of photo-sensing semiconductor dice to said substrate, each said photo-sensing semiconductor die defining at least one photo-sensing area opposing said front surface of one said unit substrate portion for receiving light impinging upon said backside surface and passing through said unit substrate portion thereof;
(d) establishing a plurality of lens housings each including at least one lens element;
(e) coupling a plurality of lens housings to said substrate to pre-form a plurality of said photo-sensing device packages, each said lens housing being disposed on said backside surface of one said unit substrate portion, each said lens element thereof being disposed in optical alignment with said semiconductor die disposed over said front surface of said unit substrate portion; and,
(f) dicing said substrate to separate said unit substrate portions one from the other to form said plurality of photo-sensing device packages.

11. The method as recited in claim 10 wherein step (e) includes attaching each said lens housing to said backside surface of one said unit substrate portion by epoxy adhesive joint.

12. The method as recited in claim 10 wherein said predetermined range of wavelengths includes the visible range of wavelengths.

13. The method as recited in claim 12 wherein said substrate is formed of a glass material substantially transparent to light in the visible range of wavelengths.

14. The method as recited in claim 10 wherein each said photo-sensing semiconductor die is spaced from said front surface of one said unit substrate portion by a gap, and a sealing structure is formed between each said photo-sensing semiconductor die and said unit substrate portion to extend about and enclose said gap for defining a sealed cavity between said photo-sensing area and a portion of said unit substrate portion front surface.

15. The method as recited in claim 10 further comprising before step (c) the step of applying on each said unit substrate portion an optical coating for varying the transmittance therethrough of light within said predetermined range of wavelengths.

16. The method as recited in claim 10 further comprising before step (c) the step forming at least one patterned metal layer on said front surface of each said unit substrate portion, and at least one patterned passivation layer on said patterned metal layer having a plurality of openings to define a plurality of bonding pads.

17. The method as recited in claim 10 wherein step (c) includes connecting a plurality of bonding pads formed on each said photo-sensing semiconductor die to said substrate by a plurality of flipchip bumps.

18. A method of fabricating a plurality of photo-sensing device packages comprising the steps of:
(a) establishing a substrate formed of a material substantially transparent to light within a visible range of wavelengths;
(b) defining on said substrate a plurality of unit substrate portions each having front and backside surfaces on opposite sides thereof;
(c) forming on each said unit substrate portion at least one set of patterned metal and passivation layers defining a plurality of bonding pads;
(d) establishing a plurality of photo-sensing dice each having a plurality of bonding pads;
(e) flipchip mounting said photo-sensing semiconductor dice respectively on said unit substrate portions, said bonding pads of each said photo-sensing semiconductor die being connected to said substrate by flipchip bumps, each said photo-sensing semiconductor die defining at least one photo-sensing area opposing said front surface of one said unit substrate portion for receiving light impinging upon said backside surface and passing through said unit substrate portion thereof;
(f) establishing a plurality of lens housings each including at least one lens element;
(g) mounting said lens housings respectively on said backside surfaces of said unit substrate portions, said lens element of each said lens housing being disposed in optical alignment with said semiconductor die disposed over said front surface of one said unit substrate portion; and,
(h) dicing said substrate to separate said unit substrate portions one from the other to form the photo-sensing device packages.

19. The method as recited in claim 18 wherein said lens housings are mounted to said substrate by epoxy adhesive joint material formed using a process selected from the group consisting of: a screen printing process, a stencil printing process, a needle dispensing process, and a stamping process.

20. The method as recited in claim 18 wherein said lens housings are mounted serially upon said unit substrates, each said lens housing being automatically picked and dipped in an epoxy adhesive material for placement upon one said unit substrate portion, said epoxy adhesive material being cured to join said lens housing to said unit substrate portion.
